(19) United States
(12) Patent Application Publication
(10) Pub. No.: US 2016/0060450 A1
(43) Pub. Date: Mar. 3, 2016

(54) SEALING SHEET, METHOD FOR MANUFACTURING SEALING SHEET, AND METHOD FOR MANUFACTURING ELECTRONIC COMPONENT PACKAGE

(71) Applicant: NITTO DENKO CORPORATION, Ibaraki-shi, Osaka (JP)

(72) Inventors: Eiji Toyoda, Ibaraki-shi, Osaka (JP); Yusaku SHIMIZU, Ibaraki-shi, Osaka (JP); Jun ISHII, Ibaraki-shi, Osaka (JP)

(21) Appl. No.: 14/779,859

(22) PCT Filed: Mar. 17, 2014
(86) PCT No.: PCT/JP2014/057168

§ 371 Date: Sep. 24, 2015

(30) Foreign Application Priority Data
Mar. 27, 2013 (JP) 2013-066999
Feb. 7, 2014 (JP) 2014-022295

(51) Int. Cl. C08L 65/02; H03H 9/64

(52) U.S. Cl. CPC C08L 65/02; H03H 9/64

(57) ABSTRACT

Provided are a sealing sheet having excellent flexibility and capable of producing an electronic component package which is highly reliable even if an object to be sealed has a hollow structure, a method for manufacturing the sealing sheet, and a method for manufacturing the electronic component package. The present invention is a sealing sheet containing dispersed domains of an elastomer, the domains having a maximum diameter of 20 μm or less.

### TECHNICAL FIELD

The present invention relates to a sealing sheet, a method for manufacturing the sealing sheet, and a method for manufacturing an electronic component package.

### BACKGROUND ART

For production of an electronic component package for a semiconductor or the like, typically a procedure is employed in which one or more electronic components fixed to a substrate, a temporary fixing material or the like are sealed with a sealing resin, and the sealed product is diced as necessary so that a package is formed per each electronic component. A sheet-shaped sealing resin having good handling ability is used as the sealing resin. A technique of blending a sheet for sealing with a filler by kneading is proposed as a method for increasing the blending amount of a filler for an improvement in the performance of a sealing sheet (Patent Document 1).

### PRIOR ART DOCUMENTS

### Patent Documents

Patent Document 1: JP-A-2013-7028

### SUMMARY OF THE INVENTION

### Problems to be Solved by the Invention

The increase in the blending amount of the filler in the sealing sheet can provide a reduction in warpage caused after heat curing and by heating during solder reflow or the like, and produce a highly reliable electronic component package. However, the increase causes deterioration in the flexibility of the sealing sheet, which may cause deterioration in handling ability.

In recent years, micro electronic components referred to as MEMS such as an SAW (Surface Acoustic Wave) filter, a CMOS (Complementary Metal Oxide Semiconductor) sensor, and an accelerometer have been developed along with a semiconductor package. These electronic components generally have a hollow structure for propagating a surface elastic wave, maintaining an optical system, and securing the movability or the like of a movable member. It is necessary to maintain a hollow structure during sealing so that the operation reliability of the movable member and the connection reliability of an element are secured. The correspondence of the sealing sheet to an object to be sealed which has such a hollow structure is also required.

An object of the present invention is to provide a sealing sheet having excellent flexibility and capable of producing an electronic component package which is highly reliable even if an object to be sealed has a hollow structure, a method for manufacturing the sealing sheet, and a method for manufacturing an electronic component package.

### Means for Solving the Problems

The present inventors have conducted intensive studies, and resultantly found that the problems described above can be solved by employing the following constitution, thus arriving at the present invention.

That is, the present invention is a sealing sheet containing dispersed domains, of an. elastomer, the domains having a maximum diameter of 20 μm or less.

In the sealing sheet, the elastomer is dispersed while forming the domains, and thereby excellent flexibility can be exhibited and good handling ability is obtained. In the sealing sheet, minute domains having a maximum diameter of 20 μm or less (hereinafter, merely referred to as “minute domains”) are uniformly dispersed. The minute domains provide a thixotropic function to a micro region of, particularly a few of micrometer orders to a few hundreds of micrometer orders, and can act to regulate the flow of other component caused by heating during sealing. As a result, for example, the inflow of the component to the void of an electronic component having a hollow structure is suppressed, and thereby the hollow structure can be maintained. Therefore, a highly reliable electronic component package can be produced. In the macro region of a few hundreds of micrometer orders, the component flows in the entire sealing sheet including the minute domains, which provides excellent flattery property of the sealing sheet to the unevenness of the electronic component. The maximum diameter of the domains means a maximum distance between two points on an outline in the observation image of each of the domains . When a plurality of elastomer particles are present in an aggregation state or a flocculation state in the observation image, elastomer particles having a successive outline are treated as one domain. A procedure for observing the domains and a method for measuring the maximum diameter are based on the description of Examples.

In the sealing sheet, the elastomer preferably contains a rubber component . The rubber component is preferably at least one selected from the group consisting of a butadiene-based rubber, a styrene-based rubber, an acrylic rubber, and a silicone-based rubber. The elastomer contains such a component, which can exhibit the flexibility of the sealing sheet and a flow regulation function in a micro region at a high level.

In the sealing sheet, the content of the elastomer is preferably 1.0% by weight or more and 3.5% by weight or less. Thereby, the sealing sheet can suitably exhibit flexibility, and the embedding property of the electronic component can be secured by exhibiting a moderate melt viscosity.

Preferably, the sealing sheet further contains a thermosetting resin. The heat resistance and stability over time of the electronic component package obtained by sealing can be improved.

In the sealing sheet, a ratio Ee/Et of a tensile modulus Ee of the elastomer to a tensile modulus Et of the thermosetting resin at 60° C. is preferably 5×10⁻⁵ or more and 1×10⁻² or less. During kneading in the manufacture process of the sealing sheet, a shear stress from the thermosetting resin effectively acts on the elastomer, which can provide the promotion of the minute elastomer.

The present invention includes a method for manufacturing a sealing sheet. The method includes: a kneading step of preparing a kneaded product containing an elastomer; and a forming step of forming the kneaded product in a sheet shape to obtain the sealing sheet, wherein in the kneading step, kneading is performed so that the elastomer of the sealing sheet is dispersed in a form of domains and a maximum diameter of the domains is set to 20 μm or less.

According to the method for manufacturing the sealing sheet of the present invention, the sealing sheet can be efficiently manufactured.

In the method, a ratio r/t of the number of rotations for kneading r (rpm) to a kneading treatment amount t (kg/hr) in the kneading step is preferably 60 or more. When r/t of 60 or more, a sufficient shear stress is applied to kneading raw materials containing the elastomer, which can efficiently provide the promotion of the minute elastomer.

The present invention also includes a method for manufacturing an electronic component package. The method includes: a laminating step of laminating the sealing sheet onto one or more electronic components so as to cover the electronic components; and a sealed body forming step of curing the sealing sheet to form a sealed body.

### BRIEF DESCRIPTION OF THE DRAWINGS

FIG. 1 is a sectional view schematically showing a sealing sheet according to one embodiment of the present invention.

FIG. 2A is a sectional view schematically showing one step of a method for manufacturing an electronic component package according to one embodiment of the present invention.

FIG. 2B is a sectional view schematically showing one step of a method for manufacturing an electronic component package according to one embodiment of the present invention.

FIG. 2C is a sectional view schematically showing one step of a method for manufacturing an electronic component package according to one embodiment of the present invention.

FIG. 3 is a SEM observation image of a cutting plane of a sealing sheet in Examples of the present invention.

### MODE FOR CARRYING OUT THE INVENTION

### First Embodiment

### [Sealing Sheet]

A sealing sheet according to the present embodiment will be described with reference to FIG. 1. FIG. 1 is a sectional view schematically showing a sealing sheet according to one embodiment of the present invention. A sealing sheet 11 is typically provided in a state of being laminated on a support 11a such as a polyethylene terephthalate (PET) film. The support ila may be subjected to a mold release treatment for easily peeling off the sealing sheet 11.

In the sealing sheet 11, domains of an elastomer are dispersed, and the maximum diameter of the domains is 20 μm or less. The elastomer may locally aggregate or flocculate. From the viewpoint of a flow regulation function, it is preferable that the domains are entirely uniformly dispersed. The upper limit of the maximum diameter of the domains is not particularly limited as long as the upper limit is 20 μm or less, and preferably 15 μm or less, and more preferably 10 μm or less. From the viewpoint of the physical limit of miniaturization and the application of flexibility, the lower limit of the maximum diameter of the domains is preferably 0.1 μm or more, and more preferably 0.3 μm or more.

The sealing sheet has a coefficient of linear expansion of, preferably 15 ppm/K or less at 20° C. after being heat-cured at 150° C. for 1 hour, and more preferably 10 ppm/K or less. Thereby, the warpage of an electronic component package can be satisfactorily suppressed. A method for measuring the coefficient of linear expansion is as follows. An uncured sealing sheet having a width of 4.9 mm, a length of 25 mm, and a thickness of 0.2 mm is cured at 150° C. for 1 hour. The cured resin sheet is set in TMA8310 (manufactured by Rigaku Corporation), to measure a coefficient of linear expansion of the resin sheet at a tensile load of 4.9 mN and a temperature increase rate of 10° C./min.

A resin composition which forms the sealing sheet is not particularly limited as long as the resin composition can suitably provide characteristics described above, can be used for resin-sealing of an electronic component such as a semiconductor chip, and contains an elastomer. From the viewpoint of improving the heat resistance and stability of the cured sealing sheet, preferably, the resin composition further contains a thermosetting resin in addition to the elastomer. Specific examples of the preferred resin composition include epoxy resin compositions containing components A to E shown below.

Component A: epoxy resin

Component B: phenol resin

Component C: elastomer

Component D: organic filler

Component E: curing accelerator

### (Component A)

An epoxy resin (component A) as the thermosetting resin is not particularly limited. Various kinds of epoxy resins can be used such as, for example, a triphenylmethane-type epoxy resin, a cresol novolac-type epoxy resin, a biphenyl-type epoxy resin, a modified bisphenol A-type epoxy resin, a bisphenol A-type epoxy resin, a bisphenol F-type epoxy resin, a modified bisphenol F-type epoxy resin, dicyclopentadiene-type epoxy resin, a phenol novolac-type epoxy resin and a phenoxy resin. These epoxy resins may be used alone or in combination of two or more thereof.

An epoxy resin which has an epoxy equivalent of 150 to 250 and a softening point or melting point of 50 to 130° C. and is solid at ordinary temperature is preferred from the viewpoint of securing toughness after curing of the epoxy resin and reactivity of the epoxy resin, and particularly a triphenylmethane-type epoxy resin, a cresol novolac-type epoxy resin and a biphenyl-type epoxy resin are preferred from the viewpoint of reliability.

A modified bisphenol A-type epoxy resin having a flexible backbone of an acetal group, a polyoxyalkylene group or the like is preferred from the viewpoint of low stress, and a modified bisphenol A-type epoxy resin having an acetal group can be especially suitably used because it is liquid and has good handling characteristics.

The content of the epoxy resin (component A) is preferably set in a range of 1 to 10% by weight based on the total amount of the epoxy resin composition.

### (Component B)

The phenol resin (component B) is not particularly limited as long as it can be used as the thermosetting resin and it causes a curing reaction with the epoxy resin (component A). For example, a phenol novolac resin, a phenol aralkyl resin, a biphenyl aralkyl resin, a dicyclopentadiene-type phenol resin, a cresol novolac resin, a resol resin and the like are used. These phenol resins may be used alone or in combination of two or more thereof.

As the phenol resin, a phenol resin having a hydroxyl equivalent of 70 to 250 and a softening point of 50 to 110° C. is preferably used from the viewpoint of reactivity with the epoxy resin (component A), and particularly a phenol novolac resin can be suitably used because of its high curing reactivity. A phenol resin having low hygroscopicity, such as a phenol aralkyl resin and a biphenyl aralkyl resin, can also be suitably used from the viewpoint of reliability.

The epoxy resin (component A) and the phenol resin (component B) are blended in such a ratio that the total amount of hydroxyl groups in the phenol resin (component B) is preferably 0.7 to 1.5 equivalents, more preferably 0.9 to 1.2 equivalents, based on 1 equivalent of epoxy groups in the epoxy resin (component A) from the viewpoint of curing reactivity.

### (Component C)

An elastomer (component C) used with the epoxy resin (component A) and the phenol resin (component B) is not particularly limited as long as it can form the above-mentioned predetermined domains, and various acrylic copolymers and rubber components or the like can be used, for example. From the viewpoint that the dispersibility of the component C in the epoxy resin (component A), and the heat resistance, flexibility, and strength of the obtained sealing sheet can be improved, the component C preferably contains a rubber component. The rubber component is preferably at least one selected from the group consisting of a butadiene-based rubber, a styrene-based rubber, an acrylic rubber, and a silicone-based rubber. These may be used alone or in combinations of two or more.

The content of the elastomer (component C) is 1.0 to 3.5% by weight, preferably 1.0 to 3.0% by weight based on the total amount of the epoxy resin composition. If the content of the elastomer (component C) is less than 1.0% by weight, it becomes difficult to secure the plasticity and flexibility of the sealing sheet 11, and further it becomes difficult to perform resin sealing while suppressing the warp of the sealing sheet. If conversely the above-described content is more than 3.5% by weight, there is the tendency that the melt viscosity of the sealing sheet 11 is increased to deteriorate the embedding property of an electronic component, and the strength and heat resistance of a cured body of the sealing sheet 11 are reduced.

The weight ratio of the elastomer (component C) to the epoxy resin (component A) (weight of component C/weight of component A) is preferably set in a range of 0.5 to 1.5. This is because if the weight ratio is less than 0.5, it becomes difficult to control the fluidity of the sealing sheet 11, and if the weight ratio is more than 1.5, there is the tendency that the tackiness of the sealing sheet 11 to an electronic component is deteriorated.

A ratio Ee/Et of a tensile modulus Ee of the elastomer to a tensile modulus Et of the thermosetting resin at 60° C. is preferably 5×10⁻⁵ or more and 1×10⁻² or less, and more preferably 2×10⁻⁴ or more and 4×10⁻³ or less. Thereby, a shear stress from a kneading member and the thermosetting resin effectively acts on the elastomer during kneading in the manufacture process of the sealing sheet, which can provide the promotion of the minute elastomer. A method for measuring the tensile moduli Ee and Et can be performed according to the following procedure. Each of sheets made of the elastomer and the thermosetting resin is cut out in a strip shape having a thickness of 200 μm, a length of 400 mm, and a width of 10 mm by a cutter knife to produce a measurement sample. The tensile modulus and loss elastic modulus of the measurement sample at −50 to 300° C. are measured under conditions of a frequency of 1 Hz and a temperature increase rate of 10° C./min using a solid viscoelasticity measuring device (Model: RSA-III manufactured by Rheometric Scientific, Inc.) The value of the tensile modulus at 60° C. during the measurement is read, to obtain intended tensile moduli Ee and Et.

### (Component D)

The inorganic filler (component D) is not particularly limited, various kinds of previously known fillers can be used, and examples thereof include powders of quartz glass, talc, silica (fused silica, crystalline silica, etc.), alumina, aluminum nitride, silicon nitride and boron nitride. They may be used alone or in combination of two or more thereof.

Particularly, silica powders are preferably used because the thermal linear expansion coefficient of a cured body of the epoxy resin composition is reduced to thereby reduce internal stress, and resultantly the warp of the sealing sheet 11 after sealing of an electronic component can be suppressed, and among silica powders, a fused silica powder is more preferably used. Examples of the fused silica powder include a spherical fused silica powder and a crushed fused silica powder, but a spherical fused silica powder is especially preferably used from the viewpoint of fluidity. Particularly, those having an average particle diameter of 54 μm or less are preferably used, those having an average particle diameter ranging from 0.1 to 30 μm are further preferably used, and those having an average particle diameter ranging from 0.5 to 20 μm are especially preferably used.

The average particle diameter can be derived by making a measurement with a laser diffraction scattering grain size distribution measuring device using a sample that is randomly extracted from a population.

The content of the inorganic filler (component D) is preferably 70 to 90% by volume (81 to 94% by weight since a silica particle has a specific gravity of 2.2 g/cm³), more preferably 74 to 85% by volume (84 to 91% by weight in the case of a silica particle), and still more preferably 76 to 83% by volume (85 to 90% by weight in the case of a silica particle) based on the total amount of the epoxy resin composition. If the content of the inorganic filler (component ID) is less than 70% by volume, there is the tendency that the warp of the sealing sheet 11 is increased because the linear expansion coefficient of a cured body of the epoxy resin composition is increased. On the other hand, if the above-described content is more than 90% by volume, there is the tendency that tackiness with an electronic component is reduced because the plasticity and fluidity of the sealing sheet 11 are deteriorated.

### (Component E)

The curing accelerator (component E) is not particularly limited as long as it causes curing of the epoxy resin and the phenol resin to proceed, but organic phosphorus-based compounds such as triphenylphosphine and tetraphenylphosphonium tetraphenylborate, and imidazole-based compounds are suitably used from the viewpoint of curability and keeping quality. These curing accelerators may be used alone or in combination with other curing accelerators.

The content of the curing accelerator (component E) is preferably 0.1 to 5 parts by weight based on 100 parts by weight of the total of the epoxy resin (component A) and the phenol resin (component B).

### (Other Components)

To the epoxy resin composition may be added a flame retardant component in addition to the components A to E. As the flame retardant component, various kinds of metal hydroxides such as, for example, aluminum hydroxide, magnesium hydroxide, iron hydroxide, calcium hydroxide, tin hydroxide and conjugated metal hydroxides can be used.

The average particle diameter of the metal hydroxide is preferably 1 to 10 μm, further preferably 2 to 5 μm from the viewpoint of securing appropriate fluidity when the epoxy resin composition is heated. If the average particle diameter of the metal hydroxide is less than 1 μm, it becomes difficult to uniformly disperse the metal hydroxide in the epoxy resin composition, and sufficient fluidity may not be achieved during heating of the epoxy resin composition. If the average particle diameter is more than 10 μm, there is the tendency that the flame retardant effect is reduced because the surface area per added amount of the metal hydroxide (component E) is decreased.

As the flame retardant component, not only the above-mentioned metal hydroxides but also a phosphazene compound can be used. As the phosphazene compound, for example, SPR-100, SA-100 and SP-100 (each manufactured by Otsuka Chemical Co., Ltd.), FP-100 and FP-110 (each manufactured by FUSHIMI Pharmaceutical Co., Ltd.) and the like are available as commercial products.

A phosphazene compound represented by the formula (1) or (2) is preferred because it exhibits a flame retardant effect even in a small amount, and the content of phosphorus elements contained in the phosphazene compound is preferably 12% by weight or more.

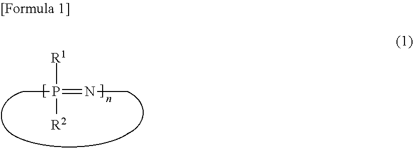

(wherein, n is an integer of 3 to 25, R¹ and R² are the same or different, and are each a monovalent organic group having a functional group selected from the group consisting of an alkoxy group, a phenoxy group, an amino group, a hydroxyl group and an allyl group.)

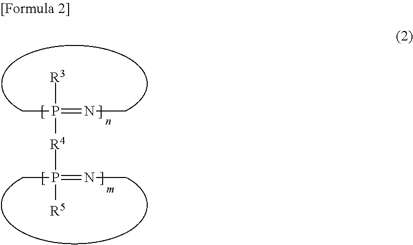

(wherein, n and m are each independently an integer of 3 to 25. R³ and R⁵ are the same or different, and are each a monovalent organic group having a functional group selected from the group consisting of an alkoxy group, a phenoxy group, an amino group, a hydroxyl group and an allyl group. R⁴ is a divalent organic group having a functional group selected from the group consisting of an alkoxy group, a phenoxy group, an amino group, a hydroxyl group and an allyl group.)

A cyclic phosphazene oligomer represented by the formula (3) is preferably used from the viewpoint of stability and suppression of generation of voids.

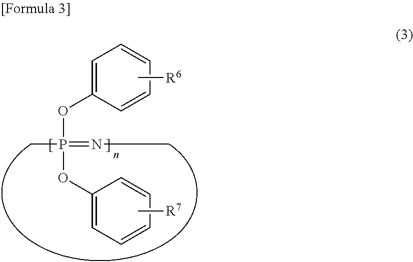

(wherein, n is an integer of 3 to 25, and RG and R⁷ are the same or different, and are each hydrogen, a hydroxyl group, an alkyl group, an alkoxy group or a glycidyl group.)

As the cyclic phosphazene oligomer represented by the above formula (3), for example, FP-100 and FP-110 (each manufactured by FUSHIMI Pharmaceutical Co., Ltd.) and the like are available as commercial products.

The content of the phosphazene compound is preferably 10 to 30% by weight based on the total amount of organic components including the epoxy resin (component A), the phenol resin (component B) and the elastomer (component D) and the curing accelerator (component B) and the phosphazene compound (other components) which are contained in the epoxy resin composition. That is, if the content of the phosphazene compound is less than 10% by weight based on the total amount of the organic components, there is the tendency that the flame retardancy of the sealing sheet 11 is deteriorated, and followability to the unevenness of an adherend (e.g., a substrate on which an electronic component is mounted) is deteriorated, leading to generation of voids. If the content is more than 30% by weight of the total amount of the organic components, there is the tendency that tacking easily occurs on the surface of the sealing sheet 11, so that workability is deteriorated, e.g., it becomes difficult to perform positioning to an adherend.

The above-mentioned metal hydroxide and phosphazene compound can also be used in combination to obtain the sealing sheet 11 which is excellent inflame retardancy while retaining flexibility required for sheet sealing. By using the metal hydroxide and the phosphazene compound in combination, sufficient flame retardancy when only the metal hydroxide is used and sufficient flexibility when only the phosphazene compound is used can be obtained.

Among the above-described flame retardants, it is desirable to use an organic flame retardant from the viewpoint of deformability of a sealing sheet during molding of resin-sealing, followability to the unevenness of an electronic component and an adherend, and adhesion to the electronic component and the adherend, and particularly a phosphazene-based flame retardant is suitably used.

The epoxy resin composition may appropriately contain other additives such as pigments including carbon black as necessary in addition to the components described above.

### (Method for Manufacturing Sealing Sheet)

A method for manufacturing a sealing sheet will be described below. A method for manufacturing a sealing sheet of the present embodiment includes: a kneading step of preparing a kneaded product containing an elastomer; and a forming step of forming the kneaded product in a sheet shape to obtain the sealing sheet, wherein in the kneading step, kneading is performed so that the elastomer of the sealing sheet is dispersed in a form of domains and a maximum diameter of the domains is set to 20 μm or less.

### (Kneading Step)

First, an epoxy resin composition is prepared by mixing the components described above. The mixing method is not particularly limited as long as the components are uniformly dispersed and mixed. Thereafter, a kneaded product is prepared by kneading the blend components containing an elastomer directly with a kneader or the like. In this case, kneading is performed so that the elastomer of the sealing sheet is dispersed in a form of domains and a maximum diameter of the domains is set to 20 μm or less.

Specifically, components including the components A to E and other additives as necessary are mixed using known means such as a mixer, and the mixture is then melt-kneaded to prepare a kneaded product. The method for performing melt-kneading is not particularly limited, and examples thereof include methods of performing melt-kneading by a known kneader such as a mixing roll, a pressure kneader or an extruder. As the above-mentioned kneader, for example, a kneader can be suitably used, which includes a kneading screw having, a portion where in a part of a shaft direction, the protrusion amount of a screw blade from a screw shaft is smaller than the protrusion amount of a screw blade from a screw shaft in other portions, or a kneading screw having, in a part of a shaft direction, no screw blade. In the portion where the protrusion amount of a screw blade is small or the portion having no screw blade, the shearing force and stirring level are lowered, and consequently the compression ratio of a kneaded product is increased, so that entrapped air can be removed, thus making it possible to suppress generation of pores in the kneaded product obtained.

Kneading conditions are not particularly limited as long as the temperature is equal to or higher than the softening points of the components described above, and the temperature is, for example, 30 to 150° C., and preferably 40 to 140° C., further preferably 60 to 120° C. when considering the heat-curability of the epoxy resin, and the time is, for example, 1 to 30 minutes, preferably 5 to 15 minutes. In this way, a kneaded product can be prepared.

When the kneader is used for kneading, a ratio r/t of the number of rotations for kneading r (rpm) to a kneading treatment amount t (kg/hr) is preferably 60 or more, and more preferably 70 or more. When the ratio r/t is 60 or more, a sufficient shear stress is applied to kneading raw materials containing the elastomer, which can efficiently provide the promotion of the minute elastomer. The number of rotations for kneading r (rpm) is preferably 200 to 1000 rpm, and the kneading treatment amount t (kg/hr) is preferably 3 to 20 kg/hr.

### (Molding Step)

Through molding the resulting kneaded product into a sheet-like shape by extrusion molding, the sealing sheet 11 can be obtained. Specifically, the kneaded product after melt-kneading is extrusion-molded while it is kept at a high temperature without being cooled, whereby the sealing sheet 11 can be formed. The extrusion method for this purpose is not particularly limited, and examples thereof include a T die extrusion method, a rolling method, a roll kneading method, a co-extrusion method and a calender molding method. The extrusion temperature is not particularly limited as long as it is equal to or higher than the softening points of the components described above, but the extrusion temperature is, for example, 40 to 150° C., preferably 50 to 140° C., further preferably 70 to 120° C. when considering the heat curability and moldability of the epoxy resin. In this way, the sealing sheet 11 can be formed.

The thickness of the sealing sheet 11 is not particularly limited, and is preferably 100 to 2000 μm. In the above-mentioned range, the electronic component can be satisfactorily sealed. The reduction in the thickness of the resin sheet can provide a reduction in an amount of heat generation, which is less likely to cause shrinkage on curing. As a result, the amount of the warpage of the package can be reduced, and a more reliable electronic component package is obtained.

The sealing sheet thus obtained may be laminated as necessary so as to have a desired thickness, and used. In other words, the sealing sheet may be used in the form of a monolayer structure, or may be used as a laminate formed by laminating the sealing sheet into a multilayer structure having two or more layers.

### [Method for Producing Electronic Component Package]

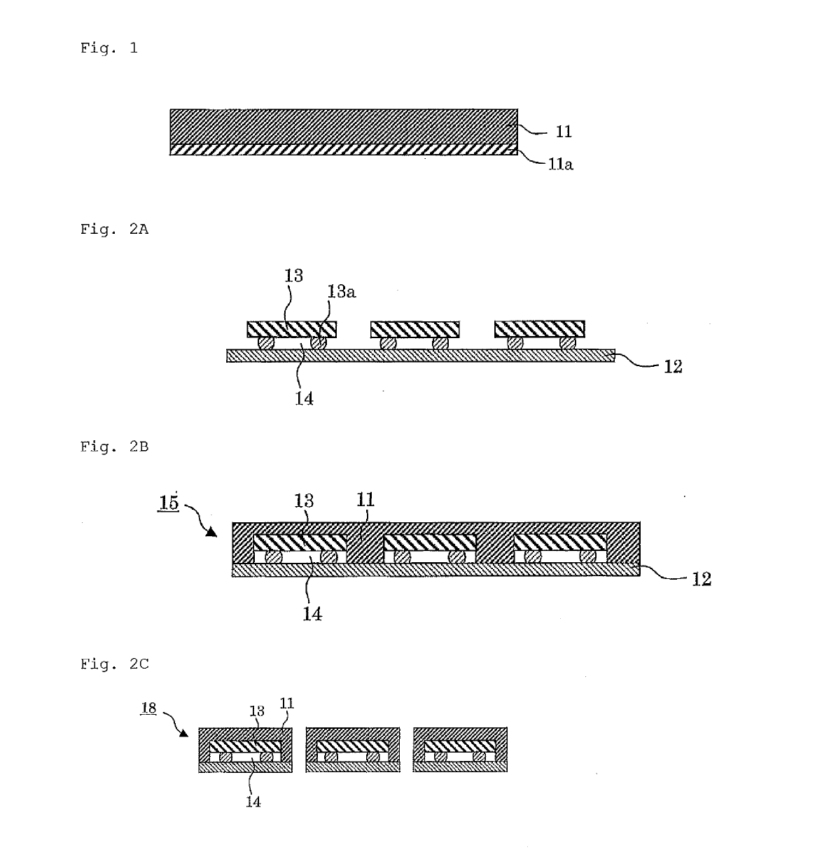

Next, a method for producing an electronic component package according to this embodiment, which uses the sealing sheet described above, will be described with reference to FIGS. 2A to 2C. FIGS. 2A to 2C are sectional views each schematically showing one step of a method for producing an electronic component package according to one embodiment of the present invention. In this embodiment, electronic components mounted on a substrate are hollow sealed with a sealing sheet to prepare an electronic component package. In this embodiment, SAW filters are used as an electronic component, and a printed wiring substrate is used as an adherend, but elements other than those mentioned above may be used. For example, a capacitor, a sensor device, a light emitting element, a vibration element or the like can be used as the electronic component, and a lead frame, a tape carrier or the like can be used as the adherend. Alternatively, the electronic component may be temporarily fixed on a temporary fixing material, and then resin-sealed without using the adherend. Regardless of which of the elements is used, a high level of protection of the electronic component by resin sealing can be achieved. Although the hollow sealing is performed, solid sealing may be performed so that the hollow portion is not included by using an underfill material or the like depending on an object to be sealed.

### (SAW Chip Mounting Substrate Providing Step)

In an SAW chip mounting substrate providing step, a printed wiring substrate 12 on which a plurality of SAW chips 13 are mounted is prepared (see FIG. 2A). The SAW chips 13 can be formed by dicing a piezoelectric crystal on which a predetermined comb-shaped electrode is formed, into individual pieces by a known method. For mounting the SAW chips 13 onto the printed wiring substrate 12, a known device such as a flip chip bonder or a die bonder can be used. The SAW chip 13 and the printed wiring substrate 12 are electrically connected via a protruded electrode 13a such as a bump. Between the SAW chip 13 and the printed wiring substrate 12, a hollow portion 14 is maintained so that the propagation of the surface elastic wave on the surface of the SAW chip is not impaired. A distance between the SAW chip 13 and the printed wiring substrate 12 is determined according to the specification of each element, and is generally about 15 to 50 μm.

### (Sealing Step)

In a sealing step, the sealing sheet 11 is laminated to the printed wiring substrate 12 so as to cover the SAW chips 13, and the SAW chips 13 are resin-sealed with the sealing sheet (see FIG. 2B). The sealing sheet 11 serves as a sealing resin for protecting the SAW chips 13 and elements associated therewith from the external environment.

In this embodiment, by employing the sealing sheet 11, the SAW chips 13 can be embedded and covered merely by bonding the sealing sheet 11 onto the printed wiring substrate 12, so that the production efficiency of the semiconductor package can be improved. In this case, the sealing sheet 11 can be laminated on the printed wiring substrate 12 by a known method such as heat pressing or a laminator. For heat pressing conditions, the temperature is, for example, 40 to 100° C., preferably 50 to 90° C., the pressure is, for example, 0.1 to 10 MPa, preferably 0.5 to 8 MPa, and the time is, for example, 0.3 to 10 minutes, preferably 0.5 to 5 minutes. When considering the adhesion and followability of the sealing sheet 11 to the SAW chips 13 and the printed wiring substrate 12, it is preferred to perform pressing preferably under a reduced pressure condition (e.g., 0.1 to 5 kPa).

Since the minute domains of the elastomer are dispersed in the sealing sheet 11, the infiltration of the resin component to the hollow portion 14 is suppressed, and the operation reliability and connection reliability of the SAW chip 14 can be improved.

### (Sealed Body Forming Step)

In a sealed body forming step, the sealing sheet is subjected to a heat curing treatment to form a sealed body 15 (see FIG. 2B). Regarding conditions for the heat curing treatment of the sealing sheet, the heating temperature is preferably 100° C. to 200° C., more preferably 120° C. to 180° C., the heating time is preferably 10 minutes to 180 minutes, more preferably 30 minutes to 120 minutes, and a pressure may be applied as necessary. When a pressure is applied, a pressure of preferably 0.1 MPa to 10 MPa, more preferably 0.5 MPa to 5 MPa can be employed.

### (Dicing Step)

Thereafter, a sealed body 15 including elements such as the sealing sheet 11, the printed wiring substrate 12, and the SAW chips 13 maybe diced (see FIG. 2C). Thereby, an electronic component package 18 can be obtained per each SAW chip 13. The sealed body 15 is usually diced in a state where the sealed body 15 is fixed by a conventionally known dicing sheet.

### (Substrate Mounting Step)

A substrate mounting step of subjecting the electronic component package 18 obtained as described above to rewiring and bump formation, and mounting the electronic component package 18 on another substrate (not shown) can be performed as necessary. For mounting the electronic component package 18 on the substrate, a known device such as a flip chip bonder or a die bonder can be used.

### Second Embodiment

In the first embodiment, blended components are kneaded with a kneader or the like to prepare a kneaded product, and the kneaded product is formed into a sheet by extrusion molding. On the other hand, in the present embodiment, a varnish prepared by dissolving or dispersing components in an organic solvent or the like is applied and formed into a sheet. In the applying method, a sheet can be formed in a state where the elastomer is dissolved or dispersed in the solvent or the like, which can provide the minute domain size of the elastomer.

As a specific preparation procedure using a varnish, the components A to E and other additives as necessary are appropriately mixed in accordance with a usual method, and the mixture is uniformly dissolved or dispersed in an organic solvent to prepare a varnish. Then, the varnish is applied onto a support of polyester or the like, and dried, whereby the sealing sheet 11 can be obtained. A release sheet such as a polyester film may be laminated as necessary for protecting the surface of the sealing sheet. The release sheet is peeled off at the time of sealing.

The organic solvent is not particularly limited, and various kinds of previously known organic solvents, for example, methyl ethyl ketone, acetone, cyclohexanone, dioxane, diethyl ketone, toluene, ethyl acetate and the like can be used. They may be used alone or in combination of two or more thereof. Normally, it is preferred to use the organic solvent in such a manner that the solid concentration of the varnish ranges from 30 to 95% by weight.

The thickness of the sheet after drying of the organic solvent is not particularly limited, but is normally set to preferably 5 to 100 μm, more preferably 20 to 70 μm, from the viewpoint of uniformity of the thickness and the amount of a residual solvent.

### EXAMPLES

Preferred Examples of the present invention will be illustratively described in detail below. However, for the materials, the blending amounts, and the like described in Examples, the scope of the present invention is not intended to be limited thereto unless definitely specified. The part(s) means “part(s) by weight”.

### Example 1

### (Production of Sealing Sheet)

The following components were blended by a mixer. The blended components were melt-kneaded at 110° C. for 10 minutes with the number of rotations for kneading set to 300 rpm and a kneading treatment amount set to 5 kg/hr by a biaxial kneader. The melt-kneaded product was then extruded from a T die to produce a sealing sheet having a thickness of 200 μm.

| | | |
|---|---|---|
| Epoxy resin: bisphenol F-type epoxy resin (YSLV-80XY | 3.4 | Parts |
| (epoxy equivalent: 200 g/eq.; softening point: 80° C.) | | |
| manufactured by Nippon Steel Chemical Co., Ltd.) | | |
| Phenol resin: phenol resin having a biphenyl aralkyl | 3.6 | Parts |
| backbone (MEH-7851-SS (hydroxyl equivalent: 203 g/eq.; | | |
| softening point: 67° C.) manufactured by MEIWA | | |
| PLASTIC INDUSTRIES, LTD.) | | |
| Elastomer: (METABLEN C-132E manufactured by | 2.3 | Parts |
| Mitsubishi Rayon Co., Ltd.) | | |
| Inorganic filler: spherical fused silica (FB-9454FC | 87.9 | Parts |
| manufactured by DENKI KAGAKU KOGYO | | |
| KABUSHIKI KAISHA) | | |
| Silane coupling agent: epoxy group-containing silane | 0.5 | Part |
| coupling agent (KBM-803 manufactured by Shin-Etsu | | |
| Chemical Co., Ltd.) | | |
| Carbon black (MA600 manufactured by Mitsubishi | 0.1 | Part |
| Chemical Corporation) | | |
| Flame retardant: (FP-100 manufactured by FUSHIMI | 1.8 | Parts |
| Pharmaceutical Co., Ltd.) | | |
| Curing accelerator: imidazole-based catalyst (2PHZ-PW | 0.4 | Part |
| manufactured by SHIKOKU CHEMICALS | | |
| CORPORATION) | | |

### Example 2

A sealing sheet was produced in the same manner as in Example 1 except that a kneading treatment amount was set to 3.5 kg/hr.

### Example 3

A sealing sheet was produced in the same manner as in Example 1 except that the number of rotations for kneading was set to 500 rpm.

### Example 4

A sealing sheet was produced in the same manner as in Example 1 except that the number of rotations for kneading was set to 1000 rpm.

### Example 5

The following components were dissolved or dispersed in a 1: 1 mixed solvent of methyl ethyl ketone and toluene to produce a varnish having a solid content of 40% by weight.

| | | |
|---|---|---|
| Epoxy resin: bisphenol F-type epoxy resin (YSLV-80XY | 3.4 | Parts |
| (epoxy equivalent: 200 g/eq.; softening point: 80° C.) | | |
| manufactured by Nippon Steel Chemical Co., Ltd.) | | |
| Phenol resin: phenol resin having a biphenyl aralkyl | 3.6 | Parts |
| backbone (MEH-7851-SS (hydroxyl equivalent: 203 g/eq.; | | |
| softening point: 67° C.) manufactured by MEIWA | | |
| PLASTIC INDUSTRIES, LTD.) | | |
| Elastomer: (SIBSTAR 102T manufactured by Kaneka | 4.0 | Parts |
| Corporation) | | |
| Inorganic filler: spherical fused silica (FB-9454FC | 87.0 | Parts |
| manufactured by DENKI KAGAKU KOGYO | | |
| KABUSHIKI KAISHA) | | |
| Carbon black (#20 manufactured by Mitsubishi | 0.1 | Part |
| Chemical Corporation) | | |
| Flame retardant: (FP-100 manufactured by FUSHIMI | 1.8 | Parts |
| Pharmaceutical Co., Ltd.) | | |
| Curing accelerator: imidazole-based catalyst (2PHZ-PW | 0.1 | Part |
| manufactured by SHIKOKU CHEMICALS | | |
| CORPORATION) | | |

The varnish was applied onto a PET film subjected to a mold release treatment so that the thickness of a coated film after drying of the solvent was 50 and the coated film was dried at 120° C. for 3 minutes to obtain a resin sheet having a thickness of 50 μm. The obtained resin sheet was laminated to a thickness of 200 μm using a laminator to produce a sealing sheet having a thickness of 200 μm.

### Comparative Example 1

A sealing sheet was produced in the same manner as in Example 1 except that the number of rotations for kneading was set to 100 rpm.

### Comparative Example 2

A sealing sheet was produced in the same manner as in Example 1 except that the number of rotations for kneading was set to 50 rpm.

### (Evaluation of Flexibility of Sealing Sheet)

Each of the sealing sheets of Examples and Comparative Examples was cut out to a width of 60 mm x a length of 60 mm. The sealing sheet was slowly bent by 90 degrees in a state where both end parts of the sealing sheet (sides facing in plane view) were held, and the flexibility of the sealing sheet was estimated according to the following criteria. The results are shown in Table 1.

◯: The sealing sheet was not broken even if the sealing sheet was bent by 90 degrees.

Δ: The sealing sheet was cracked when the sealing sheet was bent by 90 degrees.

×: The sealing sheet was broken when the sealing sheet was bent by 90 degrees.

### (Observation of Domains of Elastomer)

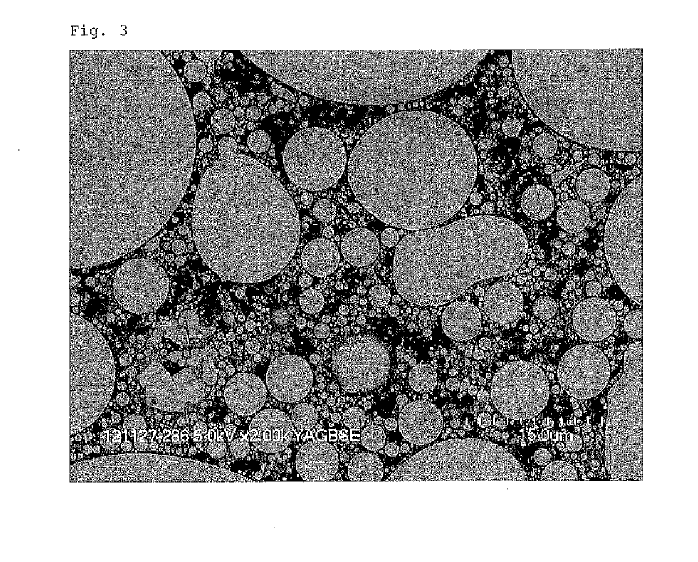

The produced sealing sheet was heat-cured for 1 hour at 150° C., and then slowly cooled to room temperature. Thereafter, the obtained cured product was cut by a cutter. The cutting plane was polished by an automatic polishing device manufactured by Buehler, and the polished cutting plane was observed by SEM (2000 magnifications). FIG. 3 shows a SEM observation image of the cutting plane of the sealing sheet of Example 1. In the SEM observation image, black regions represent the domains of the elastomer. Then, the maximum diameter of the domains was determined by selecting 50 black domains of the elastomer at random, measuring the maximum diameters of the domains, and taking the average value thereof. Examples 2 to 5 and Comparative Examples 1 and 2 were similarly subjected to SEM observation and maximum diameter measurement. The results of the maximum diameter measurement are shown in Table 1.

### (Evaluation of Infiltration Property of Resin to Package Hollow Portion)

SAW chips of the following specifications having aluminum comb-shaped electrodes were mounted on a glass substrate under the bonding conditions described below to produce an SAW chip mounting substrate.

### <SAW Chip>

Chip size: 1.4×1.1 mm square (thickness 150 μm)

Bump material: Au, thickness 30 μm

Bump number: 6 bumps

Chip number: 100 pieces (10 pieces×10 pieces)

### <Bonding Conditions>

Device: manufactured by Panasonic Electric Works Co., Ltd.

Bonding conditions: 200° C., 3 N, 1 second (ultrasonic output 2 W)

Each of sealing sheets was attached on the obtained SAW chip mounting substrate by vacuum pressing under the heating/pressing conditions shown below.

### <Attachment Conditions>

Temperature: 60° C.

Pressing force: 4 MPa

Degree of vacuum: 1.6 kPa

Pressing time: 1 minute

After releasing to atmospheric pressure, the sealing sheet was heat-cured in a hot air dryer at 150° C. for 1 hour to obtain a sealed body. An amount of infiltration of a resin to the hollow portion between the SAW chip and the glass substrate was measured by an electron microscope (“Digital Microscope” (trade name) manufactured by KEYENCE CORPORATION, 200 magnifications) from the glass substrate side. The position of the end part of the SAW chip before being sealed by the sealing sheet was confirmed and stored by the electron microscope from the glass substrate side. The amount of infiltration of the resin was determined by observing the end part by the electron microscope from the glass substrate side again after sealing, comparing observation images before and after sealing, and measuring the maximum attained distance of the resin infiltrating into the hollow portion from the end part of the SAW chip confirmed before sealing. A case where the amount of infiltration of the resin was 20 μm or less was evaluated as “◯”, and a case where the amount of infiltration of the resin was more than 20 μm was evaluated as “×”. The results are shown in Table 1.

TABLE 1

| | | Example | Example | Example | Example | Example | Comparative | Comparative |
|---|---|---|---|---|---|---|---|---|
| | | 1 | 2 | 3 | 4 | 5 | Example 1 | Example 2 |
| Number of rotations | | 300 | 300 | 500 | 1000 | Coating | 100 | 50 |
| for kneading [rpm] | | | | | | method | | |
| Kneading treatment | | 5 | 3.5 | 5 | 5 | | 5 | 5 |
| amount [kg/hr] | | | | | | | | |
| Evaluation of flexibility | | ◯ | ◯ | ◯ | ◯ | ◯ | Δ | Δ |
| Maximum diameter | | 15 | 10 | 5 | 3 | 13 | 30 | 50 |
| of domains of | | | | | | | | |
| elastomer [μm] | | | | | | | | |
| Evaluation of | Amount of | 20 | 15 | 10 | 8 | 12 | 30 | 100 |
| infiltration of | infiltration | | | | | | | |
| resin to hollow | of resin [μm] | | | | | | | |
| portion | Determine | ◯ | ◯ | ◯ | ◯ | ◯ | × | × |

As shown in Table 1, the sealing sheets of Examples 1 to 5 had good flexibility. On the other hand, Comparative Examples 1 and 2 had cracks and had poor flexibility. In Examples 1 to 5, it is found that the infiltration of the resin component to the hollow portion of the sealing sheet is suppressed in the SAW chip package produced by the sealing sheet having the minute domains of the elastomer, which allows the production of a high-quality electronic component package. In Comparative Examples 1 and 2, the amount of the infiltration of the resin to the hollow portion was more than 20 μm. This is considered to be attributable to an insufficient resin flow regulation function caused by the maximum diameter of the domains of the elastomer of more than 20 μm.

### DESCRIPTION OF REFERENCE SIGNS

11: sealing sheet

11a: support

13: SAW chip

15: sealed body

18: electronic component package

1. A sealing sheet comprising dispersed domains of an elastomer, the domains having a maximum diameter of 20 μm or less.

2. The sealing sheet according to claim 1, wherein the elastomer contains a rubber component.

3. The sealing sheet according to claim 2, wherein the rubber component is at least one selected from the group consisting of a butadiene-based rubber, a styrene-based rubber, an acrylic rubber, and a silicone-based rubber.

4. The sealing sheet according to claim 1, wherein a content of the elastomer is 1.0% by weight or more and 3.5% by weight or less.

5. The sealing sheet according to claim 1, further comprising a thermosetting resin.

6. The sealing sheet according to claim 5, wherein a ratio Ee/Et of a tensile modulus Ee of the elastomer to a tensile modulus Et of the thermosetting resin at 60° C. is 5×10⁻⁵ or more and 1×10⁻² or less.

7. A method for manufacturing a sealing sheet, the method comprising:
a kneading step of preparing a kneaded product containing an elastomer; and
a forming step of forming the kneaded product in a sheet shape to obtain the sealing sheet,
wherein in the kneading step, kneading is performed so that the elastomer of the sealing sheet is dispersed in a form of domains and a maximum diameter of the domains is set to 20 μm or less.

8. The method for manufacturing a sealing sheet according to claim 7, wherein a ratio r/t of the number of rotations for kneading r (rpm) to a kneading treatment amount t (kg/hr) in the kneading step is 60 or more.

9. A method for manufacturing an electronic component package, the method comprising:
a laminating step of laminating the sealing sheet according to claim 1 onto one or more electronic components so as to cover the electronic components; and
a sealed body forming step of curing the sealing sheet to form a sealed body.
